(19) United States
(12) Patent Application Publication
(10) Pub. No.: US 2008/0143250 A1
(43) Pub. Date: Jun. 19, 2008

(54) Organisches Leuchtbauelement

(75) Inventors: Jan Blochwitz-Nimoth, Dresden (DE); Sven Murano, Dresden (DE); Jan Birnstock, Dresden (DE)

Correspondence Address: SUTHERLAND ASBILL & BRENNAN LLP, 999 PEACHTREE STREET, N.E., ATLANTA, GA, 30309, US

(73) Assignee: NOVALED AG, Dresden (DE)

(21) Appl. No.: 11/954,628

(22) Filed: Dec. 12, 2007

(30) Foreign Application Priority Data
Dec. 14, 2006 (DE) 102006059509.2

(51) Int. Cl. H01L 27/28

(52) U.S. Cl. 313/504

(57) ABSTRACT

The invention relates to an organic lighting component, in particular an organic light-emitting diode, comprising a lighting element (1; 2) and a luminous surface (1f, 2f) encompassed by the lighting element (1; 2), the luminous surface being formed by an electrode (1a; 2a), a counterelectrode (1d; 2d), and an organic layer system (1e; 2e) which is situated between the electrode (1a; 2a) and the counterelectrode (1d; 2d) and is in electrical contact with the electrode (1a; 2a) and the counterelectrode (1d; 2d), wherein sections of the organic layer system (1e; 2e) which are located in the region of the luminous surface (1f; 2f) and which emit light upon application of an electrical voltage to the electrode (1a; 2a) and the counterelectrode (1d; 2d) have a uniform organic material structure and are provided on multiple partial electrodes (1b; 2b) of the electrode (1a; 2a) electrically connected in parallel, on one side the multiple partial electrodes being electrically connected to one another at their ends, and in which a lateral distance between adjacent partial electrodes (1b; 2b) is smaller than the width of the adjacent partial electrodes (1b; 2b).

The invention relates to an organic lighting component, in particular an organic light-emitting diode, comprising a lighting element and a luminous surface encompassed by the lighting element.

### BACKGROUND OF THE INVENTION

Organic lighting components in the form of organic light-emitting diodes (OLEDs) which emit colored light, in particular white light, have received increased attention in recent years. It is generally known that the technology of organic lighting components has a great potential for possible applications in the field of lighting technology. In the meantime, organic light-emitting diodes have attained output efficiencies in the range of conventional electric incandescent bulbs (see Forrest et al., Adv. Mat. 7 (2004) 624).

Organic light-emitting diodes are usually produced by means of a layered structure which is provided on a substrate. An organic layer system is situated in the layered structure between an electrode and a counterelectrode, so that the organic layer system can be acted on by an electrical voltage via the electrode and counterelectrode. The organic layer system is produced from organic materials, and includes a light-emitting region. Charge carriers, namely, electrons and holes, recombine in the light-emitting region, and are injected into the organic layer system when an electrical voltage is applied to the electrode and counterelectrode, and at that location are transported to the light-emitting region. A significant increase in light production efficiency has been achieved by integrating electrically doped layers into the organic layer system.

Organic lighting components may be used in various fields of application to generate light of any given color, and include in particular display devices, lighting units, and signal devices.

In one embodiment the organic lighting components may be designed in such a way that they emit white light. Such components have the potential for providing a meaningful alternative to the lighting technologies which currently dominate the market, such as incandescent lamps, halogen lamps, low-voltage fluorescent lamps, or the like.

However, significant technical problems must still be solved for a successful commercialization of the technology for organic lighting components. A particular challenge is the use of OLED components to generate large quantities of light necessary for general lighting applications. The quantity of light emitted by an OLED component is determined by two factors: the brightness in the region of the luminous surface of the component, and the size of the luminous surface. The brightness of an organic lighting component cannot be arbitrarily increased. In addition, the service life of organic components is greatly influenced by the brightness. If, for example, the brightness of an OLED component is doubled, its service life is reduced by a factor of two to four. “Service life” is defined as the elapsed time for the brightness of the OLED component to drop to one-half of its original brightness during operation at a constant current.

The luminous surface of an OLED component for lighting applications must be selected according to a desired quantity of emitted light. A luminous surface in the range of several square centimeters to greater than one square meter is sought.

OLED components are typically operated as an electrical component at low voltage in the range of approximately 2 V to approximately 20 V. The current flowing through the OLED component is determined by the luminous surface. For a relatively small luminous surface of the OLED component of approximately 100 cm², a current of 1 A would be necessary at an assumed current efficiency of 50 cd/A and an application brightness of 5000 cd/m².

However, supplying an organic lighting component with such a current represents a considerable technical problem which is not readily solved in an economical manner in commercial lighting applications. It is known that the electrical power loss from the power supply line is proportional to the electrical resistance of the supply line, and is proportional to the square of the flowing current. Thus, keeping the power loss low, even at high currents, would require electrical supply lines having a very low resistance, i.e., a large cross section. However, this must be specifically avoided in a component whose prominent feature, among others, is a flat design. If larger component surfaces are needed the supply current would have to be further increased, thus intensifying the problems with the power supply.

For this reason it has been proposed to connect multiple OLED elements in an organic lighting component in series (see GB 2 392 023 A). The overall surface of the organic lighting component is divided into individual OLED lighting elements which are electrically linked to one another in one or more series connections. The operating voltage of the lighting component is thus increased approximately by a factor which corresponds to the number of OLED lighting elements connected in series, the flowing current being reduced by the same factor. By decreasing the operating current while simultaneously increasing the operating voltage, for the same power the control of the lighting component may be greatly simplified, since it is generally much easier to provide an electrical component with a high voltage than with a high current. A further advantage resulting from the use of the series connection of OLED lighting elements is that in the event of a short circuit between the two electrodes, namely the cathode and the anode, although a portion of the luminous surface of the organic lighting component for one of the OLED lighting elements is lost, the lighting component as a whole continues to emit light, and the overall quantity of emitted light remains substantially unchanged due to the increased operating voltage for the remaining OLED lighting elements that have not failed. Thus, such a lighting component having a series connection of OLED lighting elements may continue to be used even after a short circuit of one of the OLED lighting elements. In contrast, an organic lighting component which has only a single OLED lighting element is unusable in the event of a short circuit between the anode and cathode.

However, producing OLED lighting components having a series connection of OLED lighting elements requires a complex manufacturing process. On the one hand, the electrode to be provided on the supporting substrate must be structured in order to define the electrodes associated with the individual OLED lighting elements connected in series. On the other hand it is necessary to structure the organic layer systems of the individual OLED lighting elements and the cover electrode provided thereon. Various known methods may be considered for this purpose.

In the case of OLEDs using organic materials which may be applied by vacuum evaporation, a method using shadow masks is suitable for structuring the vapor deposition. Other methods include, for example, application by LITT (laser induced thermal imaging), in which a carrier film loaded with organic material is used to transfer at least a portion of the organic material to the substrate by heating the carrier film at precise locations by use of laser. However, the LITT method may be used only for structuring of the organic layer system of the OLED lighting elements. Another structuring method must be used to structure the cover electrode, which is typically composed of metals such as silver, aluminum, or magnesium, or a conductive transparent oxide such as indium-tin oxide (ITO).

The structuring methods involve significant complexity in manufacturing the organic lighting component, resulting in high costs. When shadow masks are used, there is the additional problem of limited resolution; i.e., the distance between the OLED lighting elements connected in series is limited by the dimensions of the webs of the shadow mask. It is noted that a certain web width of the shadow mask, as a function of the size of the recesses between the webs of the shadow mask, is necessary to ensure mechanical stability of the shadow mask.

To simplify the structuring using shadow masks, it is practical to omit a fine resolution of the regions structured by use of the shadow mask. This may be achieved by designing the OLED lighting elements connected in series to be relatively large, for example having a size of approximately 1 cm². This allows the use of low-precision shadow masks which may be aligned by means of simple methods such as alignment using retaining pins. Such methods are much more favorable in mass production than methods for fine adjustment, which are based, for example, on alignment using position markers under a microscope.

Furthermore, the use of shadow masks is a limiting factor with regard to the achievable processing times, since fine adjustment of the shadow masks accounts for a considerable portion of the total process time. The process time associated with the positioning may be reduced by use of a less precise method.

For certain methods of manufacturing organic lighting components, for example the continuous roll-to-roll method, further problems result from the known use of shadow masks. On the one hand, in such a method the shadow mask must be guided together with the substrate on which the layered stack containing the electrodes and the organic layer system is to be provided, without changing the position of the shadow mask relative to the substrate. On the other hand, in such a method the shadow mask must be aligned with the substrate, whereby in the roll-to-roll method it may be necessary to hold the substrate. It is therefore desirable to have a process in which the use of high-resolution shadow masks is not necessary.

The use of less precise shadow masks does not actually result in optimization, since it is associated with significant disadvantages. It is possible only to form larger OLED subsurfaces. If one of these subsurfaces fails due to a short circuit, a large portion of the luminous surface of the component becomes inactive; i.e., it remains unlit during operation of the lighting component. As a result, however, the functionality of the overall component is severely impaired. Although there is not a large voltage drop over the short-circuited OLED lighting element in a series connection, thereby increasing the voltage for the other OLED lighting elements and only slightly changing the overall emitted light, the visual impression of the organic lighting component is significantly degraded. This is not acceptable for the intended applications, since the lighting component is perceived by the observer as defective. Furthermore, as the result of electrical short circuits in OLED components practically the entire current, which normally flows in a distributed manner over the entire surface, is conducted only through the short-circuit point. This leads to severe localized heating, resulting in ohmic losses and entailing the risk that the resistance at the short-circuit point may greatly increase and thus insulate the short-circuit point, for example due to delamination of organic or inorganic layers.

There is a risk that the encapsulation applied for protection of the lighting component may not withstand this localized thermal stress, in particular when thin-layer encapsulation is used, which is currently being considered for future OLED lighting elements. These disadvantageous effects become greater the larger the surface of the OLED component.

### SUMMARY OF THE INVENTION

The object of the invention is to provide an improved organic lighting component of the type described at the outset, in which the above-described problems of the prior art are avoided.

This object is achieved according to the invention by use of an organic lighting component according to independent claim 1. Advantageous refinements of the invention are the subject matter of the dependent subclaims.

The concept of the invention is to provide an organic lighting component, in particular an organic light-emitting diode, comprising a lighting element and a luminous surface encompassed by the lighting element, the luminous surface being formed by an electrode, a counterelectrode, and an organic layer system which is situated between the electrode and the counterelectrode and is in electrical contact with the electrode and the counterelectrode. Sections of the organic layer system which are located in the region of the luminous surface and which emit light upon application of an electrical voltage to the electrode and the counterelectrode have a uniform organic material structure and are provided on multiple partial electrodes of the electrode electrically connected in parallel, in which a lateral distance between adjacent partial electrodes is smaller than the width of the adjacent partial electrodes. In this context, a uniform organic material structure of the organic layer system in the sections on the partial electrodes connected in parallel means that light of the same color is emitted due to the similar material composition. The light may have any given color of the visible spectrum. Each of the individual sections may include emitter materials which emit light of various colors, which is then mixed for each individual section to form a mixed light in particular white light.

The provided structural design of the multiple partial electrodes of the electrode electrically connected in parallel has the advantage that the output efficiency of the overall organic lighting components remains high when, for example, a localized electrical short circuit occurs in the vicinity of one of the partial electrodes. The optical appearance of the lighting component during operation remains substantially satisfactory for the observer even in the event of such a localized electrical short circuit. The parallel connection prevents total failure of the lighting element. The provided ratio of the lateral distance between adjacent partial electrodes to the width of the adjacent partial electrodes also ensures a desired optical appearance to the observer of the luminous surface, even in the event of a short circuit.

The provided structuring of the electrode into multiple partial electrodes electrically connected in parallel may be implemented without significant additional technical complexity. In the case of a substrate-side design of the electrode, this may be achieved by use of photolithography, or also by means of a printing process. However, it is also possible to use the simple shadow mask technology, known as such, with low positioning precision. In one embodiment, particularly in conjunction with the latter-referenced technology, it is preferred for a region occupied by the organic layer system to be essentially the same size as a region occupied by the electrode together with the multiple partial electrodes. Shadow masks with low positioning precision may be used in a production process in a simple, rapid, and economical manner.

In one preferred embodiment of the invention, the lateral distance between the adjacent partial electrodes is smaller than half the width of the adjacent partial electrodes. In one practical design of the invention, the lateral distance between the adjacent partial electrodes may be smaller than one-third the width of the adjacent partial electrodes. The smaller the distance between adjacent partial electrodes in comparison to the width of the partial electrodes, the less noticeable for the optical appearance to the observer is the failure of one or more partial electrodes in the event of an electrical short circuit. Thus, it may be practical to also select the distance between adjacent partial electrodes in relation to the width of the adjacent partial electrodes in such a way that the failure of one partial electrode between two partial electrodes adjacent thereto which are still illuminated in operation is not detectable by the human eye with regard to the optical appearance.

In one advantageous embodiment of the invention the multiple partial electrodes are provided as strip electrodes. In this context, “strip electrodes” mean that along their extension the multiple partial electrodes have an essentially constant material width, as is customary for strips. The strip itself may extend, for example, along a singly or multiply curved line or zig-zag line. It is practical for curvatures or zig-zag edges of adjacent partial electrodes to engage in oppositely situated depressions, thereby enhancing the most uniform illuminated image possible for the luminous surface.

In one preferred refinement of the invention, the strip electrodes are provided so as to extend in straight lines. This provides a design which may be manufactured with the least possible technical complexity.

In one advantageous design of the invention, the organic layer system may be provided essentially continuously in the region of the luminous surface. Manufacture is simplified when the organic layer system is provided essentially continuously in the region of the luminous surface, since the organic layer system may be applied essentially in a joint manufacturing step. However, lights then operate only in the partial regions of the organic layer system located in the vicinity of the partial electrodes, while intermediate regions remain unlit. In the vicinity of the partial electrodes are provided organic components, also referred to as organic light-emitting diodes (OLED), which mutually contribute to the luminous surface. Thus, there are no adverse effects if the intermediate regions should be damaged during manufacture of the lighting element, which may occur when the electrode is provided as a cover electrode and structuring in the partial electrodes is performed by laser lithography, after which the cover electrode is applied to the organic layer system.

In one refinement of the invention, the number of multiple partial electrodes of the electrode may be at least 10, preferably at least 30, and particularly preferably at least 100. Ten partial electrodes constitute a minimum value above which the intended avoidance of total failure of the lighting component in the event of a short circuit may be achieved. When the number of partial electrodes is approximately 30, it may be assumed that in the event of a short circuit, by use of suitable scattering foils or other scattering elements the defect in a partial electrode can no longer be detected by the naked eye when the observer is located at a suitable minimum distance. If the number of partial electrodes is approximately 100, even without the use of a scattering foil a possible short circuit is no longer visible to the naked eye when the observer is located at a certain minimum distance. This information concerning the number of partial electrodes should be regarded as approximate values, since a more accurate statement about the effect of a short circuit requires not only the technical details regarding the lighting component such as electrical layer resistance of the electrode material, electrical resistance of the counterelectrode, operating voltage and current, and number and dimensions of the partial electrodes, but also information concerning the operating brightness.

In one preferred design of the invention, a maximum operating voltage for the lighting element of less than 10 V, preferably less than 6 V, and particularly preferably less than 4 V may be used. 10 V is the approximate operating voltage of a simple III-type organic light-emitting component. 6 V corresponds to the approximate operating voltage of a more complex III-type organic light-emitting component known as such in the prior art. 4 V is the approximate operating voltage of a pin-type organic light-emitting component known as such in the prior art. In addition, 10 V, 6 V, and 4 V may also be regarded as the approximate operating voltages for single-, double-, and triple-stacked pin OLEDs.

One preferred refinement of the invention provides for a maximum operating brightness in the region of the luminous surface of at least 500 cd/m², preferably at least 000 cd/m², and particularly preferably at least 5000 cd/m². The value of 500 cd/m² represents a brightness limit value above which the use of the present invention in lighting technology is regarded as particularly advantageous. If a lighting component has a total illuminating surface of 1 square meter, the luminous power at a brightness of 500 cd/m² corresponds to approximately one-half the luminous power of a 100-W incandescent bulb. A brightness of 1000 cd/m² approximately corresponds to the threshold at which a lighting element is not perceived by the observer as glaring when, for example, the lighting element is used in a lighting situation as a ceiling light. 5000 cd/m² corresponds to a brightness that is regarded as a favorable value for maximizing the luminous power per unit of illuminated surface of the lighting component, and the service life of the lighting component. For commercial optimization of a product, it may be useful to aim to achieve a brightness in this range in order to provide a weighted balance between the purchase and manufacturing costs of the component on the one hand, and the service life on the other hand.

In one advantageous embodiment of the invention, each of the multiple partial electrodes is provided with a layer resistance and a width, resulting in a product of the layer resistance and width having a value between 10 and 1000 mm*ohm/square, preferably between 100 and 1000 mm*ohm/square.

In one preferred refinement of the invention, a light-scattering element is provided so as to planarly overlap with the luminous surface. The failure of one or more partial electrodes and thus of the organic regions connected thereto, in particular as the result of an electrical short circuit, is thus suppressed in an even more effective manner with regard to the optical appearance to the observer during operation of the lighting component.

In one advantageous design of the invention, the light-scattering element comprises a light-scattering substrate on which the electrode, counterelectrode, and organic layer system are stacked.

In one refinement of the invention, the light-scattering element may comprise a scattering foil.

One preferred refinement of the invention provides that the lighting element is designed according to at least one design type selected from the following group of design types; transparent lighting element, top-emitting lighting element, bottom-emitting lighting element and a lighting element which emits on both sides.

In one practical design of the invention, the luminous surface may have an area of several square centimeters.

One advantageous embodiment of the invention provides that the organic layer system has one or more doped charge carrier transport layers. The use of doped organic layers contributes significantly to improvement of the output efficiency of organic lighting components (see, for example, DE 100 58 578 C1). A p- or n-doping or a combination thereof may be used. Use of the doping materials results in improved electrical conductivity in the electrically doped regions.

In one refinement of the invention, the lighting element is electrically connected in series with at least one additional lighting element having the same design. In this manner the electrical connection in parallel of the multiple partial electrodes in the individual lighting elements and the electrical connection in series of multiple lighting elements are combined with one another to form an organic lighting component.

In one advantageous design of the invention, the lighting element may be electrically connected in series with at least 10 additional lighting elements having the same design, preferably with at least 27 additional lighting elements, particularly preferably with at least 55 additional lighting elements. For an operating voltage of 4 V per lighting element, a series connection of 10 lighting elements results in a total voltage of 40 V, thus allowing the component to be operated by use of a voltage source corresponding to the protective extra-low voltage range. A typical voltage limit for this range is an alternating voltage of 42 V. The combination of approximately 27 components having an operating voltage of 4 V results in a total voltage of approximately 110 V for the lighting component, which is a commonly available line voltage. The combination of approximately 55 components having an operating voltage of 4 V results in a total voltage of approximately 220 V for the lighting component, which is likewise a commonly available line voltage. By adjusting the operating voltage of the lighting component to available line voltages, control of the component may be simplified by the fact that only one rectifier need be connected between the voltage source and the component. The multiple lighting elements may be configured to emit light of different colors.

It is also possible to combine two series connections in one lighting component in such a way that use is made of the available alternating voltage; i.e., for the two phases present, one of the series connections emits light. For such a configuration, the frequency of the alternating voltage power supply may be increased in order to display a continuous light emission to the observer without flickering.

The electrode together with the multiple partial electrodes electrically connected in parallel may be made of various materials. These include in particular degenerate semiconductor oxide materials or metals. In one design the electrode is made of indium-tin oxide (ITO). Since ITO may be processed by use of photolithography, which allows fine structuring for providing the partial electrodes without problems and at no additional cost, subdividing the electrode into the partial electrodes entails no additional complexity. The distance between the ITO partial electrodes may be kept very small, for example 10 μm. This results in an overall homogeneous image of the luminous surface as perceived by the human eye. If a short circuit occurs between the electrodes in such a configuration, the structuring of the ITO in partial electrodes prevents total failure of the lighting element over the entire region. The reason is that ITO has a comparatively high layer resistance, which also results in a higher resistance of the ITO partial electrodes on account of the high aspect ratio of the partial electrodes. However, since only a very low current flows through the individual partial electrodes in normal operation as a result of the parallel connection of the partial electrodes, the efficiency of the organic lighting component remains high. Only at the moment of a short circuit between the electrode and the counterelectrode is there a localized higher current, which, however, is limited by the high resistance of the ITO partial electrodes. Thus, in the event of a short circuit it is only on the surface of the affected ITO partial electrodes that no light is emitted. The remaining region of the luminous surface of the lighting element continues to be illuminated at practically unchanged brightness.

In one practical refinement of the invention, a distance between adjacently provided edge sections of the counterelectrodes of adjacent lighting elements is greater than the respective width of the multiple partial electrodes preferably greater than three times the respective width of the multiple partial electrodes, and particularly preferably greater than ten times the respective width of the multiple partial electrodes. The adjacently provided edge sections of the counterelectrodes of adjacent lighting elements are oppositely situated as viewed from above.

The proposed organic lighting component may be used for different purposes. These include in particular lighting units and display devices such as displays. In the case of a display device, pixel elements, which are individually designed according to one of the proposed embodiments of the organic lighting component, may be combined with one another to produce multicolor displays, for example RGB displays.

The proposed lighting component remains functional even in the event of severe mechanical damage. The component may be sealed against environmental influences such as atmospheric oxygen and water by use of a thin-layer encapsulation. In such a case the encapsulation is located directly on the surface of the component, and there is no cavity between the encapsulation and the layer system, as is the case for conventional encapsulation, for example by use of a glued-on glass cover. Such a configuration allows continued operation even in the event of mechanical damage, which may occur when the component is penetrated or pierced by an object. Such continued operation may be desirable, particularly in the automotive field or in military applications.

### DESCRIPTION OF PREFERRED EXEMPLARY EMBODIMENTS OF THE INVENTION

The invention is explained in greater detail below with reference to preferred exemplary embodiments, with reference to a drawing, which shows the following:

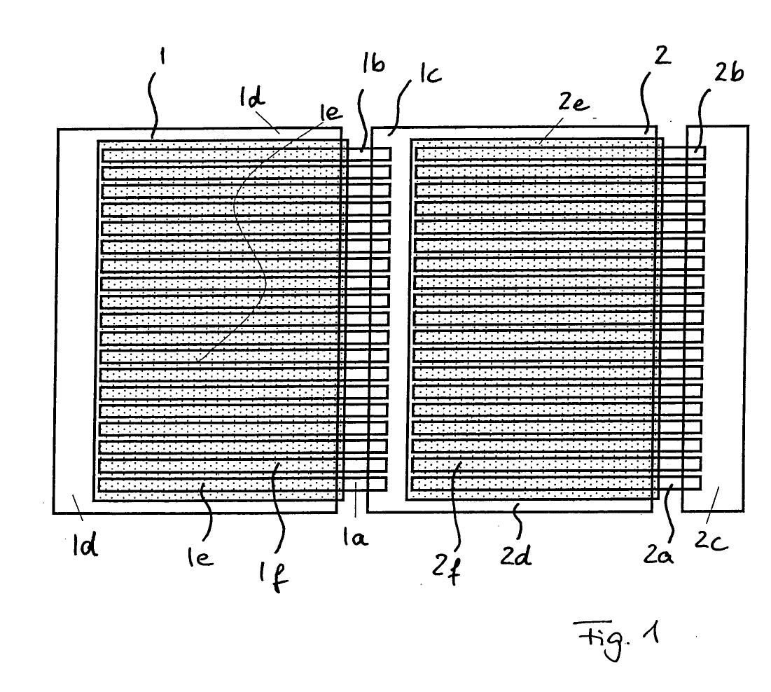

FIG. 1 shows a schematic illustration of an organic lighting component having two lighting elements electrically connected in series; and

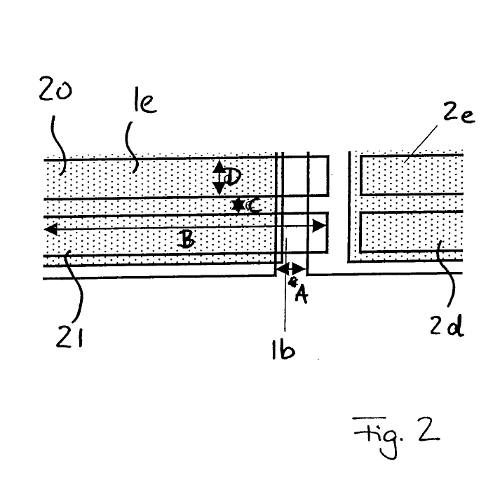

FIG. 2 shows an enlarged illustration of a section of the organic lighting component according to FIG. 1.

FIG. 1 shows a schematic illustration of an organic lighting component having two lighting elements 1, 2 electrically connected in series. Each of the two lighting elements 1, 2 has an electrode 1a, 2a which is provided as a configuration of multiple strip-shaped partial electrodes 1b, 2b extending in parallel. The partial electrodes 1b, 2b are each connected to a contact connection 1c, 2c, and are thus electrically connected in parallel. In addition, the two lighting elements 1, 2 each have a counterelectrode 1d, 2d which is provided as a flat electrode. In one simplified embodiment (not illustrated), the organic lighting component is provided by only one lighting element having a design analogous to the lighting elements 1, 2.

In the design according to FIG. 1, provided between each electrode 1a, 2a together with the partial electrodes 1b, 2b and the counterelectrode 1d, 2d is an organic stacked layer 1e, 2e, namely, a configuration of organic materials in contact with the electrode 1a, 2a and the counterelectrode 1d, 2d. The organic stacked layer 1e, 2e includes a light-emitting region, so that when an electrical voltage is applied to the electrode 1a, 2a and the counterelectrode 1d, 2d light may be produced by the lighting elements 1, 2. The associated organic stacked layer 1e, 2e has an essentially uniform material composition within the lighting element 1, 2. A luminous surface 1f, 2f, formed in each case by the partial electrodes 1d, 2d and the organic stacked layer 1c, 2e for the two lighting elements 1, 2, thus emits light of uniform color, whereby the color of the emitted light may be different for the two lighting elements 1, 2. The luminous surfaces 1f, 2f may also be provided to emit white light, which results from a mixture of light of different colors that is emitted by various organic emitter materials in the organic stacked layer 1d, 2d.

FIG. 2 shows an enlarged illustration of a section of the organic lighting component from FIG. 1. The partial electrodes 1b, 2b have a width D. The distance between adjacent partial electrodes 20, 21 is denoted by reference character C in FIG. 2. The partial electrodes 1b, 2b have a length B. In FIG. 2, reference character A denotes a distance between adjacently provided edge sections of the counterelectrodes 1d, 2d of two lighting elements.

Besides the above-described parameters, additional parameters may be used for optimizing the organic lighting component: the number of lighting elements M connected in series, the number of partial electrodes per electrode N, the resistance of the organic lighting component in operation (per surface) R, the layer resistance S, the operating brightness H, and the operating voltage U. One or more of the parameters listed above may be individually modified to adapt the general principles of the invention to the specific application.

Further exemplary embodiments are explained in detail below.

Five lighting elements connected in series are mounted on a glass substrate (not illustrated). Together, the lighting elements form the organic lighting component. A base electrode made of ITO is photolithographically structured to produce strip-shaped partial electrodes. Each of the partial electrodes is connected to a connecting contact. The length B of the partial electrodes is 20 mm, and their width D is 1 mm. The layer resistance of the ITO is 20 ohm/square. The number of parallel partial electrodes is N=100; their distance C is 20 μm. An organic layered region emitting green light and having a current efficiency E of 60 cd/A is vapor-deposited over the entire surface of each of the lighting elements. To this end, an organic stacked layer known as such is used together with the green light-emitting, phosphorescent emitter material Ir(ppy)₃ (see He et al., Appl. Phys. Lett., 85 (2004) 3911). A brightness H of 6000 cd/m² is achieved at a voltage U of 4 V and a current density of approximately 10 mA/cm². The distance A between the metallic cover electrodes of adjacent lighting elements is 3 mm.

If a short circuit then occurs in the middle of one of the partial electrodes made of ITO, the current through the OLED component provided in the vicinity of this partial electrode is limited only by the bulk resistance of the ITO feed line to the component. The lead resistance in this specific case is S*(B/2D), or 200 ohm. The factor ½ therefore signifies that the short circuit is located in the middle of the partial electrode.

All of the OLED components provided in the remaining partial electrodes are still functional. The total resistance of these OLED components, including the ITO bulk resistance, is approximately 20 ohm, which may be easily calculated from the operating voltage, the surface area, and the current density. In this case, as an approximation it is assumed that the OLED components are illuminated on the entire lighting surface with a homogeneous brightness. In fact, the OLED components are illuminated somewhat less in the regions in which a certain voltage drop occurs due to the current supply through the electrode.

Just under 10% of the current is discharged through the short circuit, and over 90% is discharged through the remaining OLED components. This also means that the lighting element still emits over 90% of the light, even in the event of such a short circuit. Despite a short circuit, light radiation of approximately 98% is still observed for the entire organic lighting component, which is composed of five such lighting elements. This is valid when the short circuit occurs in the middle of a partial electrode, If the short circuit originates even farther from the connecting contact the ITO bulk resistance becomes even greater, thereby further decreasing the short circuit current by a maximum factor of two. In other words, in this case 99% of the light is still emitted from the lighting element.

The most unfavorable position for a short circuit is in the region of the partial electrodes adjacent to the connecting contact. In that case the effective partial electrode length is only 3 mm (corresponding to the distance between two consecutively positioned metal electrodes), i.e., a lead resistance of 60 ohm. This means that the lighting element continues to be illuminated at approximately 75% brightness, and the overall organic lighting component is even illuminated at 95%. Thus, even in the most unfavorable case of a short circuit the organic lighting component continues to function very well.

The lower the ratio of A to D, the greater the effect of a short circuit close to the adjacent connecting contact. Therefore, the ratio A:D is advantageously greater than 1, preferably greater than 3, and particularly preferably greater than 10. For an A:D ratio of 1, in the event of a short circuit close to the connecting contact by use of a scattering foil a lighting component having 100 partial electrodes, for example, still appears homogeneously illuminated when observed by the naked eye, i.e., without specialized magnification means such as a magnifying glass, when the observer is located at a sufficient distance away. If the A:D ratio in this case is three, a homogeneous appearance would be achievable even without a scattering foil. For a ratio of 10, by use of a scattering foil with a strip count of 10 a homogeneous brightness could still be perceived by an observer located at a sufficient distance away.

If multiple short circuits occur simultaneously on an organic lighting component or even on a lighting element the component still remains functional although the efficiency is further reduced with each additional short circuit.

In one variant in which the lighting component is designed to be even more efficient, even in the event of a short circuit, the partial electrodes have an even thinner design. The ratio of the current through the short circuit to the current through the remaining region of the lighting element may thus be further improved. However, it is not practical to make the strip-shaped partial electrodes thinner than the typical lateral extension of a short circuit. Therefore, partial electrodes thinner than 10 μm are not meaningful.

The invention in particular enables the production yield to be markedly increased, since lighting components may still be used even when isolated short circuits have occurred.

To further improve the optimal appearance, scattering elements may be integrated into the lighting component, by means of which the non-illuminated regions between the partial electrodes as well as the regions which have failed due to short circuits are covered by scattered light from other illuminated regions.

It is also possible to structure not the substrate-side base electrode, but instead the cover electrode, in particular in strips. This may be performed, for example, by laser treatment of a flat cover electrode, which then in a manner of speaking is cut into strips. Even the regions of the organic stacked layer beneath the regions of the cover electrode to be removed may be damaged without impairing the functionality of the overall component, since the regions thus treated do not illuminate anyway.

The proposed organic lighting components, together with either one or multiple lighting elements electrically connected in series, may also be used in displays to form pixel elements, in particular for displays having very large pixel elements with a size of several square centimeters, for example for stadium screens or the like. In this case, as the result of the lighting elements the immediate failure of an entire pixel is avoided in the event of a short circuit. Instead, the observer discerns only a slightly reduced brightness of a pixel, which is not of further importance.

The loss in efficiency of the lighting component is particularly low when the components themselves provided in the region of the strip electrodes have a low ohmic resistance at the operating brightness. This is the case in particular for OLED components having electrically doped regions in the organic stacked layer.

The light radiation from the lighting component is particularly homogeneous when the luminance-voltage characteristic curve is not too steep in the region of the operating brightness. This is the case, for example, when a voltage difference of 0.4 V produces a difference in brightness of 40% maximum, preferably 20% maximum.

A simplified approximation formula results for the percentage of efficiency loss V of the proposed lighting component when a short circuit occurs at a position that is a distance K from the connecting contact of the adjacent lighting element, where A<K<B:

V=U*E/(M*N*B*H*S*K)

This results in a series of further design rules. The only variable that cannot be influenced is obviously K, the position of the short circuit. Otherwise this expression is valid, since the efficiency losses in the event of a short circuit are particularly low when
the operating voltage of the OLED components provided on the partial electrodes is small, advantageously less than 10 V, preferably less than 6 V, and particularly preferably less than 4 V;
the number of lighting elements of the organic lighting component is large, advantageously greater than 10, preferably greater than 27, and particularly preferably greater than 55;
the number of strip-shaped partial electrodes is large, advantageously greater than 10, preferably greater than 30, and particularly preferably greater than 100;
the OLED components provided on the partial electrodes are operated at sufficient brightness, advantageously with a brightness of at least 500 cd/m², preferably with a brightness of at least 1000 cd/m², and particularly preferably with a brightness of at least 5000 cd/m².

The product of S and B is considered separately. The greater the value of S, the shorter B must be, since otherwise the ohmic losses over the ITO in normal operation become too large, and the component would therefore be too inefficient. Good results are obtained when the product S*B is between 10 and 1000 mm*ohm/square, preferably between 100 and 1000 mm*ohm/square.

The features of the invention disclosed in the present specification, the claims, and the drawings may be of importance, individually as well as in any given combinations, for implementing the invention in its various embodiments.

1. Organic lighting component, in particular an organic light-emitting diode, comprising:
a lighting element and
a luminous surface encompassed by the lighting element the luminous surface being formed by an electrode, a counterelectrode, and an organic layer system which is situated between the electrode and the counterelectrode and is in electrical contact with the electrode and the counterelectrode,
wherein sections of the organic layer system which are located in the region of the luminous surface and which emit light upon application of an electrical voltage to the electrode and the counterelectrode have a uniform organic material structure and are provided on multiple partial electrodes of the electrode electrically connected in parallel, on one side the multiple partial electrodes being electrically connected to one another at their ends, and in which a lateral distance between adjacent partial electrodes is smaller than the width of the adjacent partial electrodes.

2. Lighting component according to claim 1, characterized in that the lateral distance between the adjacent partial electrodes is smaller than half the width of the adjacent partial electrodes.

3. Lighting component according to claim 1, characterized in that the lateral distance between the adjacent partial electrodes is smaller than one-third the width of the adjacent partial electrodes.

4. Lighting component according to claim 1, characterized in that the multiple partial electrodes are provided as strip electrodes.

5. Lighting component according to claim 4, characterized in that the strip electrodes are provided so as to extend in straight lines.

6. Lighting component according to claim 1, characterized in that the organic layer system is provided essentially continuously in the region of the luminous surface.

7. Lighting component according to claim 1, characterized in that the number of multiple partial electrodes of the electrode is at least 10, preferably at least 30, and particularly preferably at least 100.

8. Lighting component according to claim 1, characterized by a maximum operating voltage for the lighting element of less than 10 V, preferably less than 6 V, and particularly preferably less than 4 V.

9. Lighting component according to claim 1, characterized by a maximum operating brightness in the region of the luminous surface of at least 500 cd/m², preferably at least 1000 cd/m², and particularly preferably at least 5000 cd/m².

10. Lighting component according to claim 1, characterized in that each of the multiple partial electrodes is provided with a layer resistance and a width, resulting in a product of the layer resistance and width having a value between 10 and 1000 mm*ohm/square, preferably between 100 and 1000 mm*ohm/square.

11. Lighting component according to claim 1, characterized in that a light-scattering element is provided so as to planarly overlap with the luminous surface.

12. Lighting component according to claim 11, characterized in that the light-scattering element comprises a light-scattering substrate on which the electrode, counterelectrode, and organic layer system are stacked.

13. Lighting component according to claim 11, characterized in that the light-scattering element comprises a scattering foil.

14. Lighting component according to claim 1, characterized in that the lighting element is designed according to at least one design type selected from the following group of design types: transparent lighting element, top-emitting lighting element, bottom-emitting lighting element, and a lighting element which emits on both sides.

15. Lighting component according to claim 1, characterized in that the luminous surface has an area of several square centimeters.

16. Lighting component according to claim 1, characterized in that the organic layer system has one or more doped charge carrier transport layers.

17. Lighting component according to claim 1, characterized in that the lighting element (1) is electrically connected in series with at least one additional lighting element (2) having the same design.

18. Lighting component according claim 17, characterized in that the lighting element is electrically connected in series with at least 10 additional lighting elements having the same design, preferably with at least 27 additional lighting elements, and particularly preferably with at least 55 additional lighting elements.

19. Lighting component according to claim 17, characterized in that a distance between adjacently provided edge sections of the counterelectrodes of adjacent lighting elements is greater than the respective width of the multiple partial electrodes preferably greater than three times the respective width of the multiple partial electrodes, and particularly preferably greater than ten times the respective width of the multiple partial electrodes.

20. Use of an organic lighting component according to claim 1 in a device selected from the following group of devices: lighting unit and display device.
